(19) United States
(12) Patent Application Publication
(10) Pub. No.: US 2008/0156970 A1
(43) Pub. Date: Jul. 3, 2008

(54) Image sensor and fabricating method thereof

(75) Inventors: Chang Hun Han, Icheon-si (KR); Hea Soo Chung, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/001,652

(22) Filed: Dec. 11, 2007

(30) Foreign Application Priority Data
Dec. 27, 2006 (KR) 10-2006-0134643

(51) Int. Cl. H01L 31/0232; H01L 31/18

(52) U.S. Cl. 250/226; 438/70; 257/E21.536

(57) ABSTRACT

The present invention provides an image sensor, and methods of manufacturing the same, that includes a color filter layer on a semiconductor substrate, and a microlens array on the color filter layer, in which the microlens includes a transparent conductive layer.

The present application claims priority under 35 U.S.C. 119 and 35 U.S.C. 365 to Korean Patent Application No. 10-2006-0134643 (filed on Dec. 27, 2006), which is hereby incorporated by reference in its entirety. The present application may be related to U.S. patent application Ser. No. 11/______, filed Dec. ______ , 2007 (Attorney Docket No. SP0200705-0264US), the relevant portions of which are incorporated herein by reference.

### BACKGROUND

Embodiments of the present invention relates to an image sensor and a method for fabricating the same. Image sensors are semiconductor devices for converting optical images into electrical signals. An increase in sensitivity (e.g., the rate of converting incident light into an electrical signal) is a key consideration in the design and fabrication of image sensors.

To improve the efficiency of microlenses for condensing light, one approach has been to substantially eliminate the intervals between neighboring microlenses and create a zero-gap microlens array. This approach increases the transmission of incident light, resulting in a more efficient device.

Additional efficiency issues arise when a microlens array is formed using a photoresist film. Particles such as polymer particles, silicon particles and/or silicon dioxide particles may become attached to the microlens through a wafer backgrinding process and/or a wafer sawing process. This may degrade the sensitivity of the image sensor, thereby lowering the yield rate of the image sensors.

### SUMMARY

Embodiments of the present invention provide an image sensor, and methods for fabricating the same, capable of improving the sensitivity and the yield rate of an image sensor semiconductor device.

According to another embodiment, the image sensor includes a color filter layer on a semiconductor substrate, and a microlens on the color filter layer. The microlens includes a transparent conductive layer.

According to one embodiment, a method for fabricating an image sensor includes forming a protective layer on a lower structure including a photodiode and an interconnection, forming a color filter layer on the protective layer, forming a transparent conductive layer on the color filter layer, forming a photoresist film on the transparent conductive layer, forming a sacrificial microlens by patterning the photoresist film, and forming a microlens including the transparent conductive layer by etching the sacrificial microlens and the transparent conductive layer.

According to another embodiment, a method for fabricating an image sensor includes forming a protective layer on a lower structure including a photodiode and an interconnection, forming a color filter layer on the protective layer, forming a planarization layer on the color filter layer, forming a transparent conductive layer on the planarization layer, forming a photoresist film on the transparent conductive layer, forming a sacrificial microlens by patterning the photoresist film, and forming a microlens including a transparent conductive layer by etching the sacrificial microlens and the transparent conductive layer.

### BRIEF DESCRIPTION OF THE DRAWINGS

FIG. 1 provides a cross-sectional view schematically representing a method for fabricating an image sensor including forming a transparent conductive layer 17 and a photoresist film 19 over a color filter layer 15.

FIG. 2 provides a cross-sectional view schematically representing a method for fabricating an image sensor including forming a sacrificial microlens array 19a.

FIG. 3 provides a cross-sectional view schematically representing a method for fabricating an image sensor including forming a microlens array 17a.

### DETAILED DESCRIPTION OF THE EMBODIMENTS

In the description of the various embodiments, it will be understood that, when a layer (or film), a region, a pattern, or a structure is referred to as being “on/above” or “under/below” another substrate, another layer (or film), another region, another pad, or another pattern, it can be directly on the other substrate, layer (or film), region, pad, or pattern, or intervening layers may also be present. Furthermore, it will be understood that, when a layer (or film), a region, a pattern, a pad, or a structure is referred to as being “between” two layers (or films), regions, pads, or patterns, it can be the only layer between the two layers (or films), regions, pads, or patterns, or one or more intervening layers may also be present. Thus, it should be determined by technical idea of the invention.

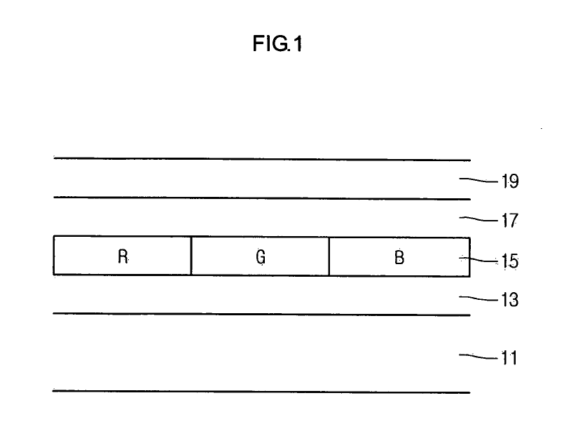

Hereinafter, the embodiments of the present invention will be described in detail with reference to accompanying drawings. FIGS. 1 to 3 are views schematically showing an exemplary method for fabricating an image sensor.

As shown in FIG. 1, in a method for fabricating the image sensor according to one embodiment, a protective layer 13 is formed on a lower structure 11, and a color filter layer 15 is formed on the protective layer 13. In one embodiment, the lower structure 11 includes a silicon semiconductor substrate (e.g., single crystal silicon wafer). The lower structure 11 may also include a light receiving unit such as a photodiode and an interconnection (e.g., a metal line on or in an insulating layer having contact plugs electrically connecting the metal line to electrical structures therebelow). More specifically, the lower structure 11 generally comprises a plurality of unit pixels, each of which contains a photodiode and a predetermined number of transistors (typically 3, 4 or 5). The color filter layer 15 may include a red color filter, a green color filter, and a blue color filter.

A method for fabricating the image sensor according to one embodiment includes forming a transparent conductive layer 17 on the color filter layer 15, and forming a photoresist film 19 on the transparent conductive layer 17. The transparent conductive layer 17 may comprise or consist essentially of an ITO (Indium Tin Oxide) layer. The ITO layer may have a thickness in the range of about 1000 Å to 6000 Å. The ITO layer may be formed by Chemical Vapor Deposition (CVD, e.g., Low Pressure CVD, High Density Plasma CVD, or Plasma Enhanced CVD) using a mixed solution that includes an indium salt and a tin salt.

Related art methods may deposit an ITO layer by sputtering. When sputtering is used, the temperature of a semiconductor substrate must be maintained at above 400° C. during the sputtering process. However, heating a substrate having a color filter layer thereon to such a temperature can damage the color filter layer. Thus, it is preferable to form the ITO layer by a CVD process.

For example, the ITO layer may be formed through the following processes. First, a diluted solution is prepared, which includes indium chloride and a tin chloride (e.g., InCl₃, and SnCl₂ or SnCl₄) dissolved in a solvent that includes an alcohol (e.g., a C1-C6 alkanol). Then, the mixed solution is sprayed onto a target (e.g., a semiconductor substrate, or layer thereon, such as a planarization layer or a color filter layer). Alternatively, the solution may be spin-coated onto the substrate, planarization layer or color filter layer.

The ITO layer may be an ITO thin film formed on a substrate, and may have a density of Sn in the range of 0.6% to 2.8%, and an absorption coefficient (α) of 2.0×10³ cm⁻¹ or less in a monochromatic light band of 800 nm.

In the method for fabricating the ITO layer according to one embodiment, the substrate is heated in air, and the ITO-forming solution including the indium salt and the tin salt is simultaneously sprayed on the substrate to form the ITO layer. The thus-formed ITO layer is substantially transparent, more so than photoresist or silicon dioxide, allowing more efficient light transmission to the underlying color filters. As a result, a transparent conductive layer 17 may be formed.

The ITO material of the transparent conductive layer 17 is more rigid and solid than that of the photoresist film. The transparent conductive layer 17 may include additional transparent or near-transparent materials and/or layers, such as Zinc Oxide (ZnO).

A photoresist film 19 is then formed over the transparent conductive layer 17. The photoresist film 19 may comprise or may be a conventional polymeric photoresist material deposited by conventional methods (e.g., spin-coating). Photoresist layer 19 may have a thickness of 200-500 nm, for example.

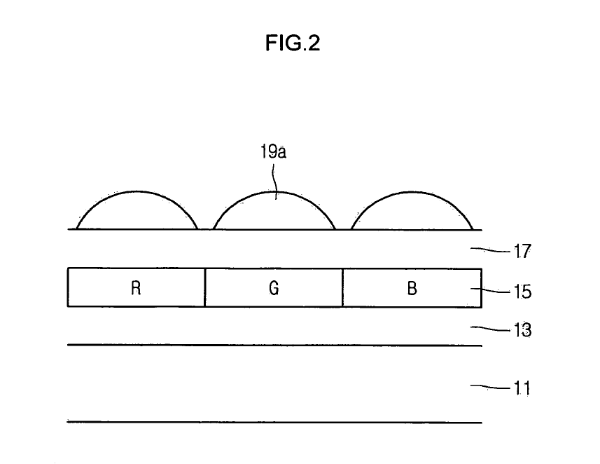

As shown in FIG. 2, the photoresist film 19 is patterned through an exposure and development process, thereby forming a sacrificial microlens array 19a having convex or curved microlenses. The sacrificial microlens array 19a is formed such that gaps between adjacent, individual microlenses are minimized. This may be accomplished by performing multiple thermal reflow processes at temperatures of from about 120° C. to 250° C. (e.g., from about 150° C. to about 200° C.). Further details of a method for reducing gaps between adjacent microlenses are described in U.S. patent application Ser. No. 11/______, filed Dec. ______ , 2007, the relevant contents of which are incorporated herein by reference.

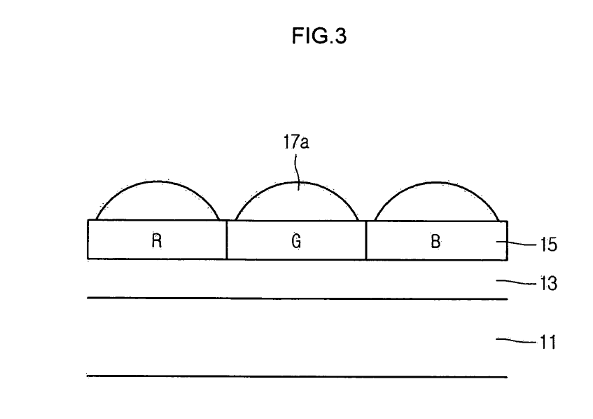

Thereafter, as shown in FIG. 3, the sacrificial microlens array 19a and the transparent conductive layer 17 are etched, thereby forming a microlens array 17a in the etched transparent conductive layer 17.

In the method for fabricating the image sensor according to one embodiment, the sacrificial microlens array 19a and the transparent conductive layer 17 are etched by non-selective (e.g., having an etch selectivity of about 1 to 1 for the sacrificial microlenses to the transparent material), directional (e.g., anisotropic) etching. The profile of sacrificial microlens array 19a, including the convex microlens topology, is transferred to the etched transparent conductive layer (e.g., the ITO layer). As a result, a microlens array 17a may be formed in the ITO material. The minimized gaps between adjacent microlenses are also transferred to the etched transparent conductive layer. Thus, the gaps between adjacent microlenses of the microlens array 17a are minimized. The minimized gaps improve the light-transmitting efficiency of the microlens array 17a.

The microlens array 17a may thus be formed in the ITO material of the transparent conductive layer, which is more transparent than photoresist or silicon dioxide. This further improves the light transmission efficiency of the microlens array 17a.

When the sacrificial microlens array 19a is gapless, the etched transparent conductive layer 17a (e.g., the ITO layer with the microlens array formed therein) may act as an electromagnetic shield for the underlying structures of the device. Alternatively, the etched transparent conductive layer 17a (e.g., the ITO layer with the microlens array formed therein) may act as an electromagnetic shield for the underlying structures of the device when the transparent conductive layer 17 is not etched completely through.

As described above, in the exemplary method(s) for fabricating the image sensor, the microlens array 17a includes a material harder than that of the photoresist material. Accordingly, it is possible to prevent particles such as polymer, silicon or silicon dioxide particles from attaching to the microlens array. As a result, the sensitivity and the yield rate of the semiconductor device can be improved.

In the method for fabricating the image sensor according to one embodiment, after the microlens array 17a is formed, the protective layer 13 may be etched such that a pad part (not shown) on the lower structure 11 is exposed.

Through the above process, a photoresist pattern (not shown) may be formed on the microlens array 17a. The photoresist film may comprise a conventional polymer photoresist material deposited by conventional methods (e.g., spin-coating). Then the resultant structure can be etched such that the pad is exposed.

In the method for fabricating the image sensor according to one embodiment, a pad can be easily exposed through one pad open (e.g., exposing) process. In addition, the pad open (exposing) process is performed as the last process in order to prevent pad corrosion that can result when a pad is exposed before the last process.

The above description concerns a process of forming a microlens array on a color filter layer. However, the method for fabricating the image sensor is not limited to the above-described embodiments alone. In an alternative embodiment, a planarization layer may be formed on the color filter layer (e.g., when the individual color filters may have different thicknesses), and a microlens array may be formed on the planarization layer. The planarization layer may comprise or consist essentially of conventional photoresist material (e.g., photoresist polymer).

Meanwhile, the description made with reference to FIGS. 1 to 3 describes embodiments where a photoresist film is formed on the transparent conductive layer with a uniform thickness to form a sacrificial microlens array. However, the photoresist film used to form the sacrificial microlens array may be formed through several processes instead of one process (e.g., multiple reflow processes). In addition, the photoresist film used to form the sacrificial microlenses may have a variable thickness in different areas of the array.

As described above, an image sensor obtained through the method for fabricating an image sensor according to the embodiments of the present invention includes a lower structure 11 having a photodiode and an interconnection thereon, and a protective layer 13 formed on the lower structure 11. In addition, a pad part may be formed on the lower structure 11. The pad part performs a function of connecting to an external signal.

In addition, the image sensor according to one embodiment includes the color filter layer 15 formed on the protective layer 13 and the microlens array 17a, including a transparent conductive layer, formed on the color filter layer 15.

In the image sensor according to the embodiments of the present invention, the microlens array 17a may be formed by using a material harder than a photosensitive material (e.g., ITO). Accordingly, it is possible to prevent particles such as polymer from being attached to the microlens array in a waver back grinding process and/or a sawing process. As a result, the sensitivity and the fabricating yield rate of a semiconductor device can be improved.

Additionally, the light transmission efficiency of a microlens array can be improved due to the transparency of the ITO layer and the minimized gaps between adjacent microlenses in the microlens array.

Any reference in this specification to “one embodiment”, “an embodiment”, “example embodiment” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a color filter layer on a semiconductor substrate; and
a microlens array on the color filter layer, in which the microlens includes a transparent conductive layer.

2. The image sensor as claimed in claim 1, further comprising a planarization layer between the color filter layer and the microlens array.

3. The image sensor as claimed in claim 1, wherein the microlens array includes an ITO layer.

4. The image sensor as claimed in claim 3, wherein the ITO layer has a thickness in a range of about 1000 Å to about 6000 Å.

5. A method for fabricating an image sensor, the method comprising:
forming a protective layer on a lower structure, including a photodiode and an interconnection;
forming a color filter layer on the protective layer;
forming a transparent conductive layer on the color filter layer;
forming a photoresist film on the transparent conductive layer;
forming a sacrificial microlens array by pattering the photoresist film; and
etching the sacrificial microlens and the transparent conductive layer to form a microlens array in the transparent conductive layer.

6. The method as claimed in claim 5, wherein etching the sacrificial microlens array and the transparent conductive layer comprises etching with a selectivity of 1:1.

7. The method as claimed in claim 5, wherein the microlens array includes an ITO layer.

8. The method as claimed in claim 7, wherein the ITO layer has a thickness in a range of about 1000 Å to about 6000 Å.

9. The method as claimed in claim 7, wherein the ITO layer is formed by a CVD process using a solution including an indium salt and a tin salt.

10. The method as claimed in claim 7, wherein the ITO layer has a density of tin (Sn) in a range of about 0.6% to 2.8%.

11. The method as claimed in claim 5, wherein the transparent conductive layer is formed by a CVD process.

12. A method for fabricating an image sensor, the method comprising:
forming a protective layer on a lower structure including a photodiode and an interconnection;
forming a color filter layer on the protective layer;
forming a planarization layer on the color filter layer;
forming a transparent conductive layer on the planarization layer;
forming a photoresist film on the transparent conductive layer;
forming a sacrificial microlens array by patterning the photoresist film; and
etching the sacrificial microlens and the transparent conductive layer to form a microlens array in the transparent conductive layer.

13. The method as claimed in claim 12, wherein etching the sacrificial microlens and the transparent conductive layer comprises etching with a selectivity of about 1:1.

14. The method as claimed in claim 12, wherein the microlens array includes an ITO layer.

15. The method as claimed in claim 14, wherein the ITO layer has a thickness in a range of about 1000 Å to about 6000 Å.

16. The method as claimed in claim 14, wherein the ITO layer is formed by a CVD process using a solution including an indium salt and a tin salt.

17. The method as claimed in claim 14, wherein the ITO layer has a density of tin (Sn) in a range of about 0.6% to about 2.8%.

18. The method as claimed in claim 12, wherein the transparent conductive layer is formed by a CVD process.

19. The method as claimed in claim 14, wherein the microlens array has an absorption coefficient (α) of 2.0×10³ cm⁻¹ or less in a monochromatic light band of 800 nm.

20. The method as claimed in claim 12, wherein the ITO layer has a density of tin (Sn) in a range of about 0.6% to 2.8%.
